(19) United States
(12) Patent Application Publication
(10) Pub. No.: US 2026/0059876 A1
(43) Pub. Date: Feb. 26, 2026

(54) Capacitor Structures

(71) Applicant: SEMICONDUCTOR COMPONENTS INDUSTRIES, LLC, Scottsdale, AZ (US)

(72) Inventors: Vincent James MCGAHAY, Poughkeepsie, NY (US); Jeffrey Peter GAMBINO, Gresham, OR (US); John W. ANDREWS, Lagrangeville, NY (US)

(73) Assignee: SEMICONDUCTOR COMPONENTS INDUSTRIES, LLC, Scottsdale, AZ (US)

(21) Appl. No.: 18/814,348

(22) Filed: Aug. 23, 2024

(51) Int. Cl. H01L 27/146

(52) U.S. Cl. CPC H10F 39/8037; H10D 1/042; H10D 1/043; H10D 1/716

(57) ABSTRACT

A system may include a capacitor. The capacitor may include a first electrode, a second electrode, and an insulator between the first and second electrodes. The first electrode may have a peripheral edge that is laterally offset from a peripheral edge of the second electrode. The laterally offset peripheral edges of the first and second electrodes may be formed using a single-mask-based etch process.

### BACKGROUND

This relates generally to systems with capacitors such as image sensors or imaging systems with capacitors.

A capacitor can include electrically conductive electrodes separated by electrically insulating material. In one illustrative implementation, an image sensor that generates image data for electronic systems or devices can include such capacitors. More specifically, an image sensor can include an image sensor array having image sensor pixels that each include one or more such capacitors.

### BRIEF DESCRIPTION OF THE DRAWINGS

FIG. 1 is a diagram of an illustrative system having one or more image sensors in accordance with some embodiments.

FIG. 2 is a diagram of illustrative image sensor circuitry having an image sensor pixel array and control and readout circuitry for the pixel array in accordance with some embodiments.

FIG. 3 is a circuit diagram of an illustrative image sensor pixel having a capacitor coupled to a floating diffusion region in accordance with some embodiments.

FIG. 4A is a side view of an illustrative capacitor in accordance with some embodiments.

FIG. 4B is a plan view of illustrative electrodes of a capacitor in accordance with some embodiments.

FIGS. 5A-5C are diagrams of illustrative capacitor structures after various processing steps in accordance with some embodiments.

FIG. 6 is a flowchart of illustrative operations for forming a capacitor in accordance with some embodiments.

### DETAILED DESCRIPTION

An electronic system may include one or more capacitors. The capacitor may include first and second electrical conductors, which are sometimes referred to as electrodes, formed from electrically conductive material. The capacitor may include an electrical insulator formed from electrically insulating material such as dielectric(s).

Configurations in which capacitors are formed as part of an electronic system having one or more image sensors that gather incoming light to capture images are sometimes described herein as illustrative examples. In one illustrative implementation, an image sensor may include an array of image sensor pixels. The pixels in the image sensor may include photosensitive elements such as photodiodes that convert the incoming light into image signals. Image sensors may have any number of pixels. For example, an image sensor may have hundreds of thousands or millions of pixels. Each of the pixels may include one or more capacitors, along with other elements such as transistors.

Other types of electronic systems such as those without image sensors may also include capacitors. In general, the formation and inclusion of capacitors of the types described in connection with the embodiments herein may be applicable to any suitable electronic system having one or more capacitors.

In illustrative configurations described herein, an electronic system may include one or more capacitors each having first and second electrodes separated by a dielectric material. For a given capacitor, the first electrode may have edges that are laterally offset from edges of the second electrode such that the first electrode has a larger profile or outline than the second electrode. The design and patterning of the first and second electrodes of the capacitor with offset edges for manufacturing may help reduce the likelihood of leakage or shorting between the first and second electrodes.

To lower manufacturing costs, the capacitor may be desirably formed using a single mask. In other words, a single mask may be used to etch both the first and second electrodes (and the dielectric material), while still achieving the desired lateral offset between edges of the first and second electrodes. In fact, in comparison with a two mask approach that etches the first and second electrodes using two different masks, a smaller lateral edge offset may be achieved with the single mask approach as mask misregistration tolerances for the two masks are not needed when a single mask is used. Accordingly, a capacitor with a smaller lateral edge offset between its two electrodes may improve energy storage density, thereby decreasing capacitor area to meet a given energy storage requirement.

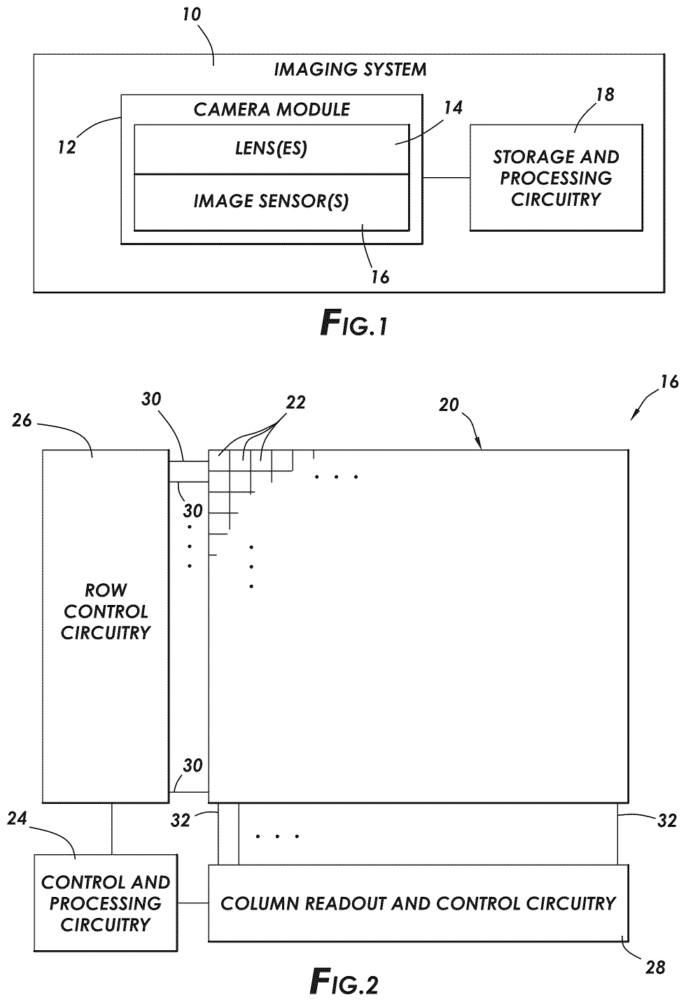

As illustrative examples, capacitors of types described above (e.g., having electrode edges that are laterally offset, having electrodes that are etched using a single mask, etc.) may be provided in an electronic system such as the system of FIG. 1. The details regarding the configuration, formation, and/or implementation of these types of capacitors are further described herein.

FIG. 1 is a functional block diagram of an illustrative imaging system such as an electronic system that uses image sensor(s) to capture images. Imaging system 10 of FIG. 1 may be a portable electronic device such as a camera, a cellular telephone, a tablet computer, a webcam, a video camera, a video surveillance system, an automotive imaging system, a video gaming system with imaging capabilities, an augmented reality and/or virtual reality system, an unmanned aerial vehicle system such as a drone, an industrial system, or any other desired imaging system or device that captures image data.

Camera module 12, sometimes referred to as an imaging module, may be used to convert incoming light into digital image data. Camera module 12 may include one or more lenses 14 and one or more image sensors 16. When capturing images, light from a scene may be focused onto each image sensor 16 by one or more lenses 14. Image sensor 16 may include circuitry for converting analog pixel image signals into corresponding digital image data that is provided to storage and processing circuitry 18.

Storage and processing circuitry 18 may include one or more integrated circuits, each serving data storage functions and/or data computation or processing functions. As examples, the one or more integrated circuits may include image processing circuits such as digital signal processors, application-specific integrated circuits, general-purpose processors, microprocessors, microcontrollers, storage devices such as voltage memory and non-volatile memory, and/or other types of integrated circuits having processors and/or memories.

Storage and processing circuitry 18 may be implemented using components that are separate from camera module 12 and/or components that form part of camera module 12. As one example, storage and processing circuitry 18 may be implemented using circuits that form part of an integrated circuit that includes an image sensor 16 or an integrated circuit within camera module 12. When storage and processing circuitry 18 is included on different integrated circuits than those of image sensors 16, the integrated circuits with storage and processing circuitry 18 may be vertically stacked or packaged with respect to the integrated circuits with image sensors 16.

Image data that has been captured by camera module 12 may be processed and stored using processing circuitry 18. As examples, an image processing engine on processing circuitry 18, an imaging mode selection engine on processing circuitry 18, and/or other types of processing engines on processing circuitry 18 may process the image data captured by camera module 12. Processing circuitry 18 may, if desired, provide processed image data to external equipment such as a computer, an external display, or other devices using wired and/or wireless communication paths.

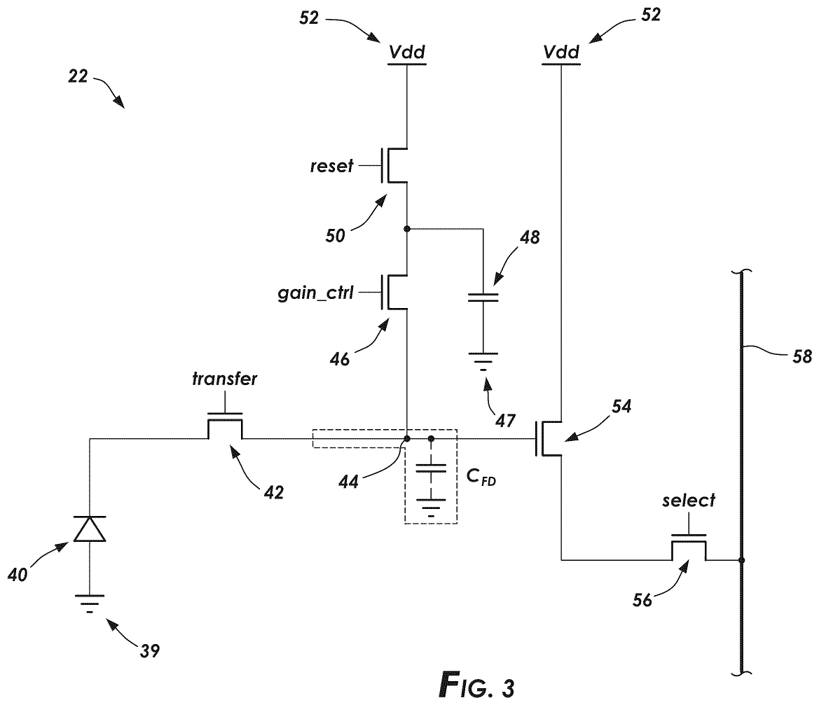

As shown in FIG. 2, an image sensor, such as an image sensor 16 included within imaging system 10 of FIG. 1, may include an image sensor pixel array such as pixel array 20 containing image sensor pixels 22, which are sometimes referred to as image pixels or pixels. These pixels 22 may be arranged in rows and columns. A row of pixels or a column of pixels may sometimes be referred to generally as a line of pixels. Image sensor 16 may include control and processing circuitry 24, sometimes referred to herein as control circuitry 24, which controls the operation of pixel array 20. Pixel array 20 may contain, for example, hundreds or thousands of rows and/or columns of image sensor pixels 22. If desired, pixel array 20 may be provided with a filter array having multiple visible color and/or non-visible filter elements each corresponding to and overlapping a respective pixel 22, thereby allowing a single image sensor to sample light of different colors and/or sets of wavelengths.

Image sensor pixels 22 may be formed in a semiconductor substrate using complementary metal-oxide-semiconductor (CMOS) technology or charge-coupled device (CCD) technology or any other suitable photosensitive device technology. Image sensor pixels 22 may be frontside illumination (FSI) image sensor pixels or backside illumination (BSI) image sensor pixels.

Control circuitry 24 may be coupled to pixel control circuitry such as row control circuitry 26 which includes row drivers that provide control signals to lines of pixels in pixel array 20 and may be coupled to pixel readout circuitry such as column readout and control circuitry 28 that read out signals from lines of pixels in pixel array 20.

Row control circuitry 26 may receive row addresses and/or signals indicative of row addresses from control circuitry 24 and supply corresponding row control signals such as reset, anti-blooming, row-select, charge transfer, dual conversion gain, and readout control signals to pixels 22 over conductive lines or paths 30 such as pixel row control paths. In particular, each pixel row may receive different control signals over a corresponding number of control paths such that each pixel row is coupled to multiple conductive paths 30. One or more conductive lines or paths 32 such as pixel column readout paths may be coupled to each column of pixels 22. Conductive paths 32 may be used for reading out image signals from pixels 22 and for supplying bias signals such as bias currents or bias voltages to pixels 22. As an example, when performing a pixel readout operation, a pixel row in pixel array 20 may be selected using row control circuitry 26 and image signals generated by the selected image pixels 22 in that pixel row can be read out along conductive paths 32.

Column readout circuitry 28 may receive image signals such as analog pixel values generated by pixels 22 over conductive paths 32. Column readout circuitry 28 may include memory or buffer circuitry for temporarily storing calibration signals such as reset level signals, reference level signals, and/or other non-image signals read out from array 20 and for temporarily storing image level signals read out from array 20, amplifier circuitry or a multiplier circuit, analog-to-digital converter (ADC) circuitry, bias circuitry, latch circuitry for selectively enabling or disabling portions of column readout circuitry 28, and/or other circuitry that is coupled to one or more columns of pixels in array 20 for operating pixels 22 and/or for reading out image signals from pixels 22. ADC circuitry in readout circuitry 28 may convert analog pixel values received from array 20 into corresponding digital pixel values, sometimes referred to as digital image data or digital pixel data. Column readout circuitry 28 may supply digital pixel data from pixels 22 in one or more pixel columns to control and processing circuitry 24 and/or processor 18 (FIG. 1) for further processing and/or storage.

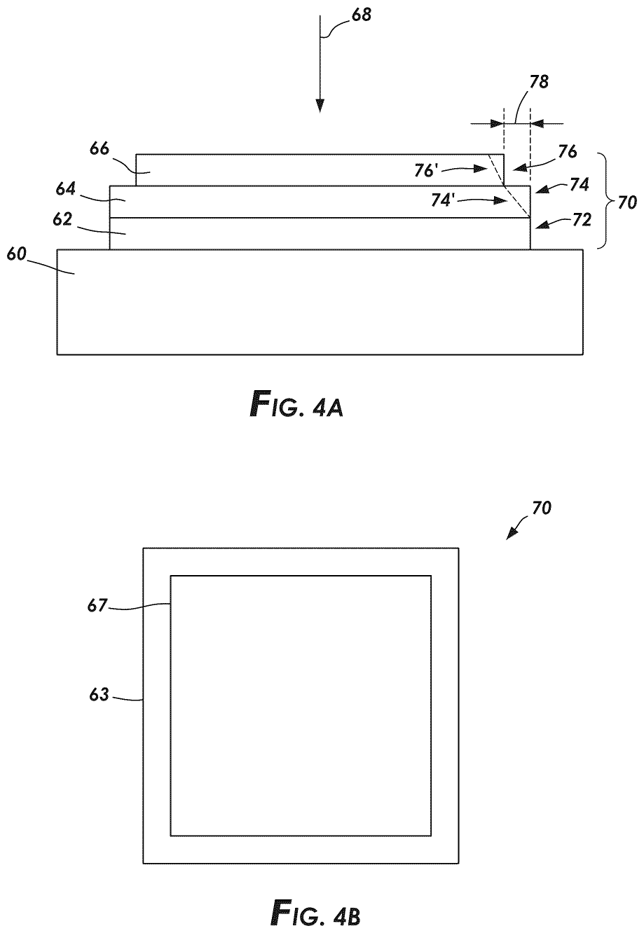

FIG. 3 is a circuit diagram of an illustrative image sensor pixel, e.g., of the type forming one or more image sensor pixels 22 in FIG. 2. As shown in FIG. 3, pixel 22 may include a photosensitive element such as photodiode 40. Photodiode 40 has a first terminal coupled to a voltage terminal 39 that receives a reference voltage, such as a ground voltage, and a second terminal at which image charge is stored. Photodiode 40 may generate charge in response to receiving incident light. The amount of charge that is generated by photodiode 40 may depend on the exposure duration or integration time, and the intensity of the incident light.

Pixel 22 in FIG. 3 may include a floating diffusion region such as floating diffusion region 44. Floating diffusion region 44 may be a doped semiconductor region such as a region in a silicon substrate that is doped by ion implantation, impurity diffusion, and/or any other doping techniques. Accordingly, floating diffusion region 44 may have an associated charge storage capacity, which is schematically shown as a capacitor having capacitance CFD in FIG. 3. Photodiode-generated charge and/or other charge, such as reset voltage level charge or dark current charge, may be generated on, transferred to, and/or stored at floating diffusion region 44 for one or more pixel readout operations.

In the example of FIG. 3, charge transfer transistor 42 receiving control signal ‘transfer’ at its gate terminal may couple photodiode 40 to floating diffusion region 44. Transistor 42 may therefore be activated, when control signal ‘transfer’ is asserted, to transfer photodiode-generated charge to floating diffusion region 44.

For high dynamic range applications, it may be desirable to extend the storage capacity of floating diffusion region 44 and operate pixel 22 in a low conversion gain mode of operation by including one or more conversion gain charge storage structures. As shown in FIG. 3, pixel 22 includes a charge storage structure such as capacitor 48. Capacitor 48 may have a first terminal coupled to a voltage terminal 47 and a second terminal that serves as its charge storage terminal. Voltage terminal 47 may supply a fixed voltage, such as a ground or supply voltage, or may supply a controllable and/or variable voltage signal that exhibits different voltage at different times.

Capacitor 48 may be coupled to floating diffusion region 44 by transistor 46 receiving control signal ‘gain_ctrl’ at its control terminal. When transistor 46 is activated, by control signal ‘gain_ctrl’ being asserted, capacitor 48 may be electrically connected to floating diffusion region 44, thereby extending the charge storage capacity of floating diffusion region 44. Additionally, when transistors 42 and 46 are both activated, when control signals ‘transfer’ and ‘gain_ctrl’ are both asserted, (a portion of) photodiode-generated charge may be transferred from photodiode 40 to capacitor 48.

To reset one or more pixel elements to a reset voltage level, pixel 22 may include one or more reset transistors such as transistor 50 receiving control signal ‘reset’ at its gate terminal. As shown in FIG. 3, transistor 50 may couple a voltage terminal 52 that receives a reference voltage, such as a power supply voltage associated with a reset voltage level, to floating diffusion region 44 via intervening transistor 46. When transistors 46 and 50 are both activated, such as when control signals ‘reset’ and gain_ctrl′ are both asserted, floating diffusion region 44 may be reset to a reset voltage level. Additionally, transistor 50 couples capacitor 48 to voltage terminal 52, and as such, also resets capacitor 48 to the reset voltage level. Transistor 50, when activated along with transistors 42 and 46, may also reset photodiode 40 to a photodiode reset voltage level.

Pixel 22 in FIG. 3 may include source follower transistor 54 coupled to voltage terminal 52 and coupled to pixel select (or row select) transistor 56. Transistors 54 and 56 may collectively form the readout portion of pixel 22. In particular, select transistor 56 has a gate terminal that is controlled by control signal ‘select’. When control signal ‘select’ is asserted and transistor 56 is activated, a corresponding pixel output signal having a magnitude that is proportional to the amount of charge at floating diffusion region 44 and/or capacitor 48 is passed, via source follower transistor 54, onto a pixel output path such as column line 58 which forms part of path 32 in FIG. 2.

In an illustrative image pixel array configuration, there are numerous rows and columns of pixels 22. A column line 58 may be associated with and coupled to each column of pixels 22. Accordingly, each image pixel 22 in a column may be coupled to the same column line 58 through a corresponding row select transistor 56. Control signal ‘select’ may be asserted to read out a pixel output signal from a selected image pixel 22 onto the shared column line 58. The pixel output signal may be provided to readout circuitry 28 (FIG. 2), and thereafter, to processing circuitry 18 (FIG. 1) for further processing.

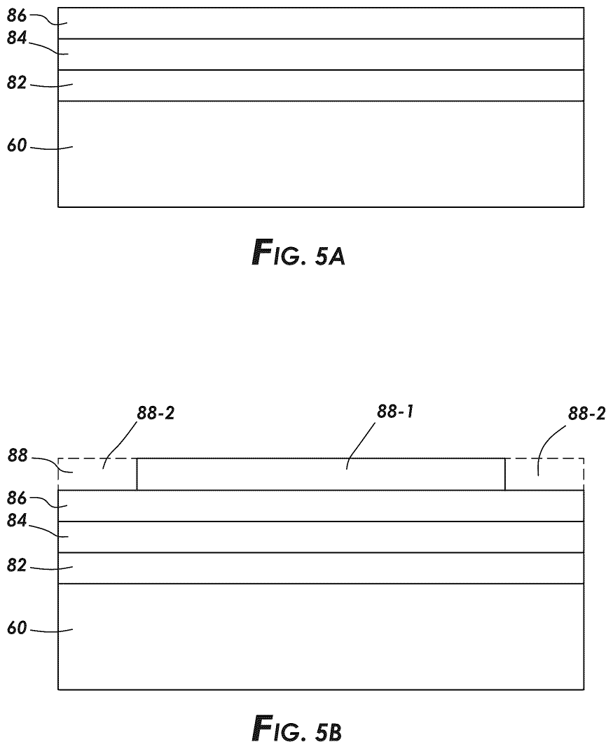

As described in the example of FIG. 3, an image sensor pixel 22 may include a capacitor such as capacitor 48. In other examples, another type of image sensor pixel 22 in FIG. 2 may include other types of capacitors, or more generally, any of image sensor 16 in FIG. 2, imaging system 10 in FIG. 1, and/or other electronic systems may include other types of capacitors, instead of or in addition to capacitors 48. Any of these types of capacitors may be formed in the manner described in connection with FIGS. 4-6. Illustrative configurations in which capacitors 48 in corresponding pixels 22 are formed in the manner described in connection with FIGS. 4-7 are described herein as examples.

FIG. 4A is a side view of an illustrative capacitor such as capacitor 70. As an example, capacitor 70 may be used to implement capacitor 48 in FIG. 3. Capacitor 70 may include capacitor structures formed on an underlying substrate 60. Substrate 60 may include a silicon dioxide layer such as a carbon-doped silicon dioxide layer, a silicon nitride layer, a polymer dielectric layer, and/or another type of dielectric layer. If desired, layers of substrate 60 may be backed and supported by and/or may be grown or deposited on the surface of an underlying silicon substrate.

An illustrative portion of substrate 60, on which capacitor structures are disposed, is shown in FIG. 4. Other portions of substrate 60 may support, provide underlying substrate layers for, and/or generally facilitate formation of other structures in the same device or system as capacitor 70. In particular, when capacitor 70 implements capacitor 48 of FIG. 3, other elements of the same pixel 22 may also be formed on substrate 60 and/or elements of other pixels in the same pixel array 20, such as multiple instances of capacitors 70 forming capacitors 48 for the different pixels of the same array 20, may be formed on substrate 60. The formation and/or inclusion of a single instance of capacitor 70 are sometimes described and illustrated herein as an example in order to not unnecessarily obscure the embodiments described herein. In general, multiple instances of capacitor 70 for the same or multiple image sensor(s), for the same or multiple die(s), for the same wafer, and/or for the same system being processed may be formed in the same manner and/or may be formed in parallel.

As shown in FIG. 4A, structures for capacitor 70 may include a first electrical conductor 62 (sometimes referred to as electrode 62) and may include a second electrical conductor 66 (sometimes referred to as electrode 66). Electrodes 62 and 66 may be formed from electrically conductive material such as metal(s) and certain metal compound(s). Configurations in which electrodes 62 and 66 are each include one or more refractory metal(s) and/or refractory metal compounds are sometimes described herein as an illustrative example. As just a few examples, electrodes 62 and 66 may each be formed from and include titanium, titanium nitride, titanium alloys, tantalum, tantalum nitride, tantalum alloys, niobium, niobium-based compounds, other types of refractory metals, and/or other types of refractory metal-based compounds. While some metal compounds such as titanium nitride, tantalum nitride, some niobium-based compounds, and/or some other refractory metal-based compounds may not necessarily be a metal, they may still form at least portion of a metal layer or electrode to enhance the functionality and/or performance of the metal layer or electrode, e.g., by forming a diffusion barrier for the metal layer and accordingly be referred to as a barrier “metal”. If desired, the metal layer or electrode may include only a combination of these refractory metal-based compounds, e.g., a combination of titanium nitride and tantalum nitride.

Structures for capacitor 70 may also include an intervening insulator 64 between electrodes 62 and 64. Insulator 64 may be formed from electrically insulating material such as dielectric(s) or dielectric material. Configurations in which insulator 64 is formed from one or more dielectric material(s) having a dielectric constant greater than 5, greater than 8, greater than 10, or greater than 12, and/or less than 50, less than 40, less than 30, less than 25, less than 20, or less than 15 are sometimes described herein as an illustrative example. In other instances, other types of dielectric material(s) may be used. As just a few examples, insulator 64 may include hafnium oxide, aluminum oxide, other dielectric materials that have a higher dielectric constant than silicon dioxide, silicon nitride, silicon dioxide, and/or other application-appropriate dielectric materials.

In the example of FIG. 4A, each of electrode 62, insulator 64, and electrode 66 may be a planar structure or layer (sometimes referred to as a plate) and may have a thickness greater than 3 nm (nanometers), greater than 5 nm, or greater than 10 nm, and/or less than 200 nm, less than 100 nm, or less than 50 nm. In other words, electrode 62 may be a bottom plate contacting a top surface of substrate 60, insulator 64 may be a middle planar layer contacting electrode 62 on a bottom side and contacting electrode 66 on a top side, and electrode 66 may be a top plate. If desired, additional structures such as additional dielectric material and/or electrical contacts for electrodes 66 and 62 may contact and/or surround any of electrode 62, insulator 64, and electrode 66.

While the example of FIG. 4A shows capacitor 70 having only planar structures (sometimes referred to as a two-dimensional capacitor structure), this is merely illustrative. If desired, portions of electrode 62, insulator 64, and electrode 66 may extend into trenches in substrate 60 or generally away from the plane in which the planar structures of capacitor 70 are shown in FIG. 4A, thereby forming a three-dimensional capacitor structure. In other words, electrode 62, insulator 64, and electrode 66 may have planar structure (or portions) in a given plane, and optionally meandering portions that extend away from the given plane.

Electrode 62 may have edges 72 that connect the top and bottom surfaces of electrode 62 on the lateral sides of electrode 62. Insulator 64 may have edges 74 that connect the top and bottom surfaces of insulator 64 on the lateral sides of insulator 64. Electrode 6 may have edges 76 that connect the top and bottom surfaces of electrode 66 on the lateral sides of electrode 66. Illustrative lateral edges 72, 74, and 76 on one side of electrode 62, insulator 64, and electrode 66, respectively, are illustrated and described in connection with FIG. 4A. These lateral edges may sometimes be referred to as peripheral edges or sidewalls.

As shown in FIG. 4A, the lateral edge 76 of electrode 66 may be laterally offset or laterally displaced with respect to lateral edge 72 of electrode 62. This lateral offset is designed to help prevent unwanted electrical connections between electrodes 62 and 66 during the manufacturing process. However, this lateral offset may also be desirably reduced or minimized to increase overlap between electrodes 62 and 66, thereby increasing capacitance and energy storage capacity (over the same overall capacitor footprint or outline set by the larger electrode 62).

Accordingly, capacitor 70 may be formed to exhibit a lateral offset separation 78 between lateral edge 76 and lateral edge 72 (and between lateral edge 76 and lateral edge 74). As examples, separation 78 may be a distance less than 100 nm, less than 90 nm, less than 80 nm, less than 50 nm, or less than 30 nm, and/or greater than 3 nm, greater than 5 nm, greater than 10 nm, or greater than 15 nm. As a more specific example, separation 78 may be a distance between 10 nm and 30 nm.

While lateral edges 72, 74, and 76 are shown in FIG. 4A to be vertical, this is merely illustrative. Depending on the mask and/or process used to etch, or generally manufacture, electrode 62, insulator 64, and electrode 66, one or more, or all, of their lateral edges may be sloped, curved, and/or generally non-vertical. For example, as illustrated in FIG. 4A, electrode 66 may have a sloped or slanted lateral edge 76′ instead of a vertical edge 76 and insulator 64 may have a sloped or slanted lateral edge 74′ instead of a vertical edge 74.

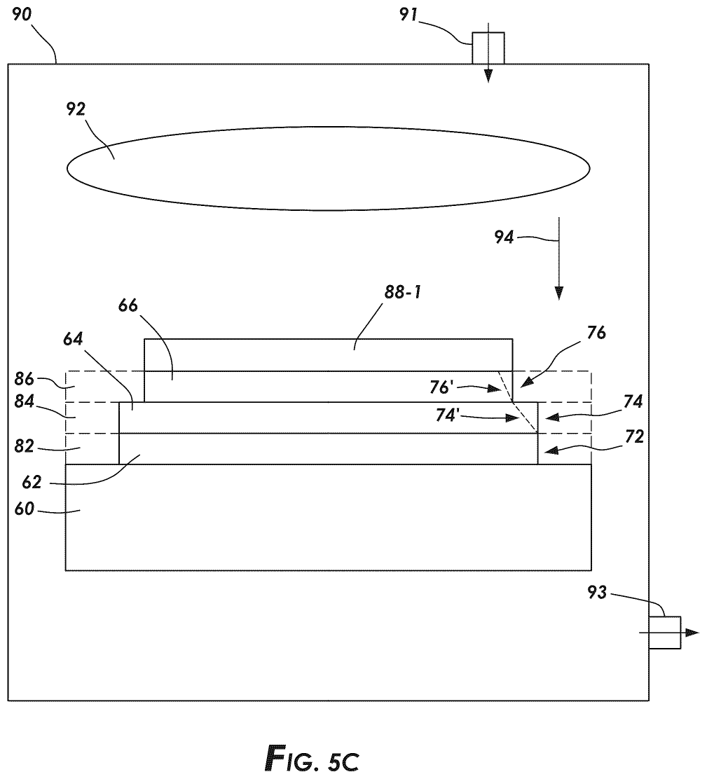

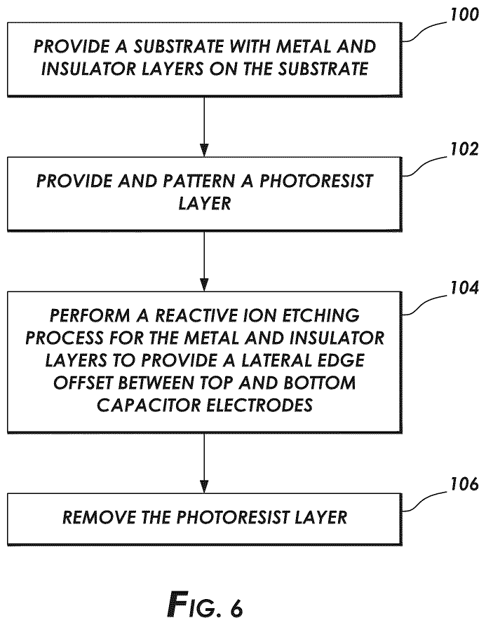

Configurations in which structures for capacitor 70 in FIG. 4A are formed (e.g., etched) using a single mask are sometimes described herein as an illustrative example. In particular, when electrode 66, insulator 64, and electrode 62 are formed based on a single mask, the etching process may result in at least insulator 64 having sloped lateral edges 74′, which in turn helps define and provide the lateral offset between edge 76 of electrode 66 and edge 72 of electrode 62 when even a single mask is used. The single-mask-based etching process may help provide but reduce the offset to separation 78, which may not be possible if a multi-mask etching processing is used because the multiple masks would require alignment tolerances greater than the feature sizes needed to form lateral separation 78 between lateral edges 72 and 76. Details for an illustrative single-mask-based etching process are further described below in connection with FIGS. 5 and 6.

Capacitor 70 may have any suitable lateral outline or footprint (defined by lateral edges 72 on all sides), depending on neighboring structures, space constraints, performance requirements, and/or other factors. A plan view of an illustrative capacitor 70 (when viewed in direction 68 in FIG. 4A and with substrate 60 omitted) is shown in FIG. 4B. In the example of FIG. 4B, capacitor 70 may have an overall footprint defined by a rectangular outline 63. Outline 63 may be defined by lateral edges, such as vertical edges 72 and/or sloped edges, on all (four) sides of a rectangular electrode 62. In some illustrative configurations, insulator 64 may have the same outline 63 or may have a different (e.g., smaller) outline than outline 63. Bottom electrode 62 may be overlapped by top electrode 66 having a smaller rectangular outline 67. In other words, top electrode 66 may be entirely overlapped by bottom electrode 62. The difference between outlines 63 and 67 may define the lateral offset separation between electrodes 62 and 66. The lateral offset separation may be the same and/or may be different along different lateral edges.

The rectangular profiles for electrodes 62 and 66, and generally the rectangular profile of capacitor 70), are merely illustrative. If desired, outlines 63 and 67 may have other shapes, may be curved, may have irregular or meandering sides, and/or may generally fit in a particular image sensor pixel layout or a particular device layout. In some configurations described herein as an example, a length and/or a width of outline 63 (and/or of outline 67) may be greater than 0.25 microns, greater than 0.5 microns, greater than 1 micron, or greater than 2 microns, and/or less than 10 microns, less than 8 microns, less than 5 microns, or less than 3 microns.

Any suitable type of processing may be used to form capacitors of the type described in connection with FIGS. 4A and 4B. An illustrative process for forming capacitors 70 is described in connection FIGS. 5A-5C. While processing of a single capacitor 70 is described in connection with FIGS. 5A-5C, this is merely illustrative. Processing of capacitors 70 may occur at the wafer level, in which a wafer containing multiple un-singulated dies each further containing multiple capacitors 70 that are collectively processed in the manner described in connection with FIGS. 5A-5C.

FIG. 5A is a diagram of illustrative metal and insulator layers on a substrate and from which capacitor structures are formed. In particular, the process of forming capacitor 70 may begin with forming or otherwise providing a substrate, such as substrate 60 as in FIG. 4A. A first layer of electrically conductive material 82, a layer of electrically insulating material 84, and a second layer of electrically conductive material 86 may be deposited, formed, or otherwise provided onto substrate 60, in sequence. Any suitable thin-film deposition techniques, such as chemical and/or physical deposition techniques for forming films with at least the above-mentioned thickness of conductor 62, insulator 64, and conductor 66, may be used to form layers 82, 84, and 86. The material(s) in layer 82 may be the same material(s) used to form conductor 62 in FIG. 4A, the material(s) in layer 84 may be the same material(s) used to form insulator 64 in FIG. 4A, and the material(s) in layer 86 may be the same material(s) used to form conductor 66 in FIG. 4A.

To form the desired capacitor features, metal and insulator layers 82, 84, and 86 may be selectively etched in certain areas. FIG. 5B is a diagram of an illustrative etch mask or etch masking layer formed on the metal and insulator layers 82, 84, and 86 to facilitate the selectively etching of certain areas of metal and insulator layers 82, 84, and 86. As an example, the mask layer may be formed from photoresist material 88 such as mid-ultraviolet or deep-ultraviolet photoresist. In other words, a layer of photoresist material 88 may be coated, deposited, or otherwise provided on metal layer 86. Thereafter, photoresist layer 88 may be patterned with a patterning mask by selectively exposing portions of layer 88 (uncovered by the patterning mask) to corresponding light to which the photoresist material is sensitive. Photoresist material 88 may be a positive or negative photoresist material. After patterning, photoresist layer 88 may be developed to remove certain portions such as portions 88-2 and other portions such as portion 88-1 remains on metal layer 86. Accordingly, portion 88-1 (sometimes referred to as etch mask layer 88-1) may form the etch mask layer for etching capacitor features to form capacitor 70 in FIG. 4A.

After forming the etch mask layer, such as etch mask layer 88-1, on metal and insulator layers 82, 84, and 86, processing may proceed with an etching process. FIG. 5C is a diagram of an illustrative etching system configured to perform etching of metal and insulator layers 82, 84, and 86 based on a single etch mask layer. Configurations in which the single-mask-based etching of metal and insulator layers 82, 84, and 86 is performed using a reactive ion etching process are sometimes described herein as an illustrative example.

In this example, the structures described in connection with FIG. 5B, or more practically, a wafer containing multiple instances of the structures described in connection with FIG. 5B, may be placed in a reactive ion etching system that includes a chamber such as vacuum chamber 90 (sometimes referred to as reactive ion etching chamber 90). Chamber 90 may maintain a gas pressure in a range between 1 millitorr and 300 millitorrs, and in an illustrative example, between 3 and 50 millitorrs. Chamber 90 may have one or more inlets 91 for supplying reactive gas(es), sometimes referred to as reaction gas(es), for the reactive ion etch process and one or more outlets 93 for removing exhaust gas(es).

As just a few examples, the gas(es) supplied to chamber 90 for the reactive ion etch process may include chlorine, fluorine, boron trichloride, sulfur hexafluoride, trifluoromethane, carbon tetrafluoride, helium, and/or nitrogen. Configurations in which boron trichloride, sulfur hexafluoride, helium, trifluoromethane, and/or carbon tetrafluoride are supplied to chamber 90 when etching metal and/or metal-based materials such as those in layers 82 and 86 are sometimes described herein as an example. Configurations in which chlorine, boron trichloride, and/or helium are supplied to chamber 90 when etching dielectric or other insulator materials such as those in layer 84 are sometimes described herein as an example.

After the appropriate reactive gases for the metal or dielectric etch are supplied to chamber 90, the reactive ion etching system may provide an electromagnetic field within chamber 90 to ionize the reactive gases and produce plasma 92. As an example, the reactive ion etching system may be an inductively coupled plasma or transformer coupled plasma reactive ion etching system.

The reactive ion etching system may provide directional electric fields within chamber 90 near layers 82, 84, and 86 and substrate 60 such that the charged ions from plasma 92 is accelerated in the presence of the directional electric fields (in direction 94) towards layers 82, 84, and/or 86. The strength or magnitude of the directional electric fields may be controlled using a (radio-frequency or generally alternating-current) bias power such as a relative bias power applied between two electrodes, one of which is coupled to substrate 60 and the other one of which is distant from substrate 60. The charged ions may bombard the metal or insulator layer being etched and physically and/or chemically etch away (dashed) portions of the metal or insulator layer, while the remaining portion of the metal or insulator layer form the corresponding capacitor structure.

In the example of FIG. 5C, three different etches respectively for metal layer 86, insulator layer 84, and metal layer 82 may be performed in sequence, all while using masking layer 88-1 to cover and protect certain portions of metal layer 86, insulator layer 84, and metal layer 82. In particular, the reactive ion etching system may first etch layer 86 using a first set of parameters to leave conductor 66 for capacitor 70, may then etch layer 84 using a second set of parameters to leave insulator 64 for capacitor 70, and may lastly etch layer 82 using a third set of parameters. As just a few illustrative examples, the parameters for etching a layer may include a selected combination of gases, the flow rate of each of the gases, a total reactive gas flow rate, a pressure of chamber 90, the strength or magnitude of the electromagnetic field for ionizing the gases characterized by a power supplied to provide the electromagnetic field, the strength or magnitude of the directional electric fields for accelerating the ions of the plasma towards the layer being etched, and the etch time.

At least some of these illustrative parameters may be the same across the first, second, and third sets of parameters for etching layers 86, 84, and 82, and/or at least some of these parameters may be different across the first, second, and third sets of parameter for etching layers 86, 84, and 82. For example, the first and third sets of parameters may be entirely or mostly the same parameters because layers 86 and 82 have the same or similar materials, dimensions, and/or other characteristics, while the first and second sets of parameters may be entirely or mostly different parameters because layers 86 and 84 have the different materials, dimensions, and/or other characteristics.

In one illustrative configuration sometimes described herein as an example, the first set of parameters used to etch layer 86 may include using boron trichloride (at a first flow rate) and sulfur hexafluoride as the input reactive gases, the second set of parameters used to etch layer 84 may include using boron trichloride (at a second flow rate greater than the first flow rate) and chlorine as the input reactive gases without sulfur hexafluoride as an input reactive gas, and the third set of parameters used to etch layer 82 may include using boron trichloride (at the first flow rate) and sulfur hexafluoride as the input reactive gases.

By using sulfur hexafluoride as a reactive gas in the first set of parameters, sputtering of the etched material in layer 86 onto other structures such as photoresist 88-1 can be reduced or minimized, thereby reducing the risk of understripping layer 86 and/or stringer-induced shorting. By using boron trichloride (at a higher flow rate) and chlorine as the reactive gases without sulfur hexafluoride in the second set of parameters, sputtering of the etched material in layer 84 onto other structures such as photoresist 88-1 can be reduced or minimized, thereby reducing the risk of understripping layer 84. By using sulfur hexafluoride as a reactive gas in the third set of parameters, sputtering of the etched material in layer 82 onto other structures such as insulator 64 and/or electrode 66 can be reduced or minimized, thereby reducing the risk of understripping layer 82 and/or stringer-induced shorting between electrode 62 and other conductive structures, such as electrode 66.

The use of boron trichloride, sulfur hexafluoride, and chlorine as reactive gases for reactive ion etching of layers 86, 84, 82 are described in the example above is merely illustrative. If desired other reactive gas(es) may be used in addition to or instead of one or more of these three reactive gases.

As described in connection with FIG. 4A, the peripheral edge 76 of conductor 66 may be formed with a lateral offset (characterized by separation 78 in FIG. 4A) from the peripheral edge 72 of conductor 62. This lateral offset between edges 72 and 76 may be achieved using the single-mask etch process described in connection with FIG. 5C.

As one illustrative example for achieving this lateral offset, the second set of parameters for etching insulator layer 84 may be configured to form a sloped edge profile after etching, as shown by sloped or slanted edge 74′, instead of a vertical edge 74. Insulator 64 may be etched to exhibit sloped edge profiles, gradually widening towards layer 82, along all peripheral edges. In other words, sloped edges 74′ may extend laterally beyond edge 76 of conductor 66 and may cover a peripheral portion of layer 82 laterally beyond edge 76. The covered peripheral portion of the first metal layer at least partly defines the lateral offset between edge 76 of top electrode 66 and the eventually formed edge 72 of bottom electrode 62.

In some illustrative configurations described herein as examples, the second set of parameters may include a bias power for providing the directional electric fields that is greater than that used in the first and/or third set of parameters, may include a maintained chamber gas pressure that is less than that used in the first and/or third set of parameters, and may include a total intake or supplied reactive gas flow rate that is greater than that used in the first and/or third set of parameters. This may desirably produce more sidewall (edge) polymer on insulator 64 as layer 84 is gradually etched, thereby contributing to the sloped edge profile of insulator 64. The sloped or widening edge profile of insulator 64 towards metal layer 82 may serve to create a smaller etch area in layer 82 relative to the larger etch area in layer 86 created by mask layer 88-1. In other words, the sloped edge profile of insulator 64 effectively serves as a mask layer for layer 82 that has a larger footprint than mask layer 88-1 for layer 86, thereby causing the lateral offset between conductors 62 and 66 when layer 82 is etched.

In addition to or instead of using the sloped edge profile of insulator 64 to cause the lateral offset, the third set of parameters may be configured to exhibit some, or more specifically a slight, degree of isotropic (side) etching in addition to the primary anisotropic etching normally attributed to reactive ion etching in the downward direction. Accordingly, while layer 82 is being etched using the third set of parameters to form conductor 62, the slight isotropic nature of the same etching may cause the peripheral edges of conductor 66 to also be etched, thereby causing the peripheral edges of conductor 66 to recede, e.g., to a sloped peripheral edge 76′ instead of edge 76 as originally formed when layer 86 is etched using the first set of parameters. This slight isotropic etching may contribute to the lateral offset between peripheral edges of conductors 66 and 62.

After etching layers 82, 84, and 86, the reactive ion etching system may remove the assembly containing capacitor structures on substrate 60 (and containing mask layer 88-1) from chamber 90. Mask layer 88-1 may further be removed to result in capacitor 70 on substrate 60, as shown in and described in connection with FIG. 4A

Because the lateral offset of peripheral edges 72 and 76 are imparted using a single etch mask layer 88-1, rather than two (or more) masks, the separation of the lateral offset may be reduced compared to scenarios in which multiple etch masks are used, because the use of multiple etch masks require minimum alignment or other types of tolerances. A smaller lateral offset contributes to greater overlap between the two conductors of the capacitor for a given area, thereby allowing a more efficient and compact device layout. This efficient use of capacitor area is especially beneficial in devices where area for active elements, such as photosensitive elements, are highly desired. Additionally, the use of the single etch mask reduces processing costs, among other advantages.

FIG. 6 is a flowchart of illustrative operations for forming capacitor structures, such as capacitors structures for capacitor 70. These illustrative operations described in connection with FIG. 6 may be performed by a semiconductor device processing system that is automated to perform one or more of these operations and/or that is manually controlled to perform one or more of these operations. The semiconductor device processing system may include numerous types of specialized equipment such as metal and insulator thin-film deposition equipment, mid-ultraviolet or deep-ultraviolet photoresist coating equipment, mid-ultraviolet or deep-ultraviolet lithography equipment, reactive ion etching equipment such as the reactive ion etching system described in connection with FIG. 5C, as just a few examples. These illustrative operations described in connection with FIG. 6 may be performed as part of a larger processing operation generally for forming elements of image sensor 16 that is performed at the wafer level, may be performed as part of other types of processing operations, or may be performed separately from other types of processing operations.

At block 100, a semiconductor device processing system may provide a substrate with metal and insulator layers on the substrate. For example, the substrate may be substrate 60 in FIGS. 4A and 5A. A first metal layer such as metal layer 82 in FIG. 5A may be deposited onto the substrate, an insulator layer such as insulator layer 84 in FIG. 5A may be deposited onto the first metal layer, and a second metal layer such as metal layer 86 in FIG. 5A may be deposited onto the insulator layer.

At block 102, the semiconductor device processing system may provide and pattern a photoresist layer. For example, a photoresist layer may be coated or otherwise provided on the topmost metal layer provided on the substrate at block 100. The topmost metal layer may be metal layer 86 in FIG. 5B and the photoresist layer may be photoresist layer 88 in FIG. 5B. The photoresist layer may be patterned using photolithography and development to remove certain portions of the photoresist layer while keeping other portions of the photoresist layer, which will serve as an etch mask for etching the metal and insulator layers on the substrate provided at block 100. For example, photoresist layer 88 in FIG. 5B may be patterned to remove portions 88-2, while keeping portion 88-1 on metal layer 86. Remaining portion 88-1 may serve as an etch masking layer during subsequent etching of metal and insulator layers on the substrate at block 104.

At block 104, the semiconductor device processing system may perform a reactive ion etching process for the metal and insulator layers to provide a lateral edge offset between the top and bottom capacitor electrodes. The reactive ion etching process may use the same etch mask provided by the photoresist layer patterned at block 102 when performing reactive ion etching of each of the metal and insulator layers. For example, etching the metal and insulator layers may result in capacitor 70 in FIG. 5C having bottom electrode 62, middle insulator 64, and top electrode 66, where bottom electrode 62 has peripheral edge(s) 72 that are laterally offset from peripheral edge(s) 76 of top electrode 66, as described in connection with FIG. 4A. Illustrative operations described in connection with FIG. 5C may be performed as part of the reactive ion etching process of block 104 to etch the metal and insulator layers.

At block 106, the semiconductor device processing system may remove the (patterned) photoresist layer formed at block 102, thereby resulting in capacitor structures on the substrate, e.g., electrode 66, insulator 64, and electrode 62 of capacitor 70 on substrate 60 in FIG. 4A.

Various embodiments have been described illustrating a capacitor having first and second conductors with offset lateral edges.

As a first example, an image sensor may include a plurality of image sensor pixels. A given image sensor pixel in the plurality of image sensor pixels may have a capacitor. The capacitor may include a first electrode having a lateral edge, a second electrode having a lateral edge that is laterally offset from the lateral edge of the first electrode using a single-mask-based etching process, and an insulator between the first and second electrodes.

If desired, the lateral edge of the second electrode may be laterally separated from the lateral edge of the first electrode by a distance less than 100 nm. If desired, the insulator may have a sloped lateral edge between the lateral edge of the second electrode and the lateral edge of the first electrode. If desired, the second electrode may have a smaller outline than the first electrode and the sloped lateral edge of the insulator may overlap the first electrode. If desired, the capacitor may be formed on a substrate, the second electrode is a top electrode, and the first electrode is a bottom electrode between the top electrode and the substrate. If desired, the given image sensor pixel may include a photosensitive element, a floating diffusion region, and a transistor that couples the capacitor to the floating diffusion region. If desired, the first electrode and the second electrode may each include a refractory metal and the insulator may include a dielectric material having a dielectric constant that is greater than 5 and less than 50.

As a second example, a method of forming a capacitor may include: forming a first metal layer, an insulator layer, and a second metal layer on a substrate; forming an etch masking layer on a portion of the second metal layer; etching the second metal layer to form a top electrode for the capacitor while the etch masking layer is on the portion of the second metal layer; etching the insulator layer to form an insulator for the capacitor while the etch masking layer is on the portion of the second metal layer; and etching the first metal layer to form a bottom electrode for the capacitor while the etch masking layer is on the portion of the second metal layer. The top electrode may be formed with an edge and the bottom electrode may be formed with an edge that is laterally offset from the edge of the top electrode.

If desired, etching the second metal layer may include performing a reactive ion etch using first and second reactive gases, such as boron trichloride and sulfur hexafluoride, and etching the insulator layer may include performing a reactive ion etch using the first reactive gas and a third reactive gas, such as boron trichloride and chlorine. If desired, etching the second metal layer may include performing a reactive ion etch using a first total reactive gas flow rate and etching the insulator layer may include performing a reactive ion etch using a second total reactive gas flow rate greater than the first total reactive gas flow rate. If desired, etching the second metal layer may include performing a reactive ion etch while providing a first gas pressure in a reactive ion etching chamber and etching the insulator layer may include performing a reactive ion etch while providing a second gas pressure, less than the first gas pressure, in the reactive ion etching chamber. If desired, etching the second metal layer may include performing a reactive ion etch while providing a directional electric field having a first magnitude toward the substrate and etching the insulator layer may include performing a reactive ion etch while providing a directional electric field having a second magnitude, greater than the first magnitude. If desired, etching the insulator layer forms an insulator with a sloped edge that covers a portion of the first metal layer laterally beyond the edge of the top electrode and the covered portion of the first metal layer at least partly defines the lateral offset between the edge of the top electrode and the edge of the bottom electrode. If desired, etching the first metal layer may include performing a reactive ion etch after etching the insulator layer and the reactive ion etch etches a portion of the top electrode to form the edge of the top electrode. If desired, the edge of the bottom electrode is laterally offset from the edge of the top electrode by a distance less than 50 nm. If desired, the first metal layer and the second metal layer may each include a refractory metal and the insulator layer may include a dielectric material having a dielectric constant that is greater than 5 and less than 50.

As a third example, a capacitor may include a first electrode on a substrate, an insulator on the first electrode, and a second electrode on the insulator. The first electrode may have a peripheral edge and the second electrode may have a peripheral edge that is laterally offset from the peripheral edge of the first electrode by a separation less than 100 nm.

If desired, the insulator may have a sloped peripheral edge between the peripheral edge of the first electrode and the peripheral edge of the second electrode. If desired, the first electrode and the second electrode may each include a refractory metal and the insulator layer may include a dielectric material having a dielectric constant that is greater than 5 and less than 50.

It will be recognized by one skilled in the art that the present exemplary embodiments may be practiced without some or all of these specific details. In other instances, well-known operations have not been described in detail in order not to unnecessarily obscure the present embodiments.

The foregoing is merely illustrative and various modifications can be made to the described embodiments. The foregoing embodiments may be implemented individually or in any combination.

What is claimed is:

1. An image sensor comprising:
a plurality of image sensor pixels, a given image sensor pixel in the plurality of image sensor pixels having a capacitor, wherein the capacitor comprises:
a first electrode having a lateral edge;
a second electrode having a lateral edge that is laterally offset from the lateral edge of the first electrode using a single-mask-based etching process; and
an insulator between the first and second electrodes.

2. The image sensor defined in claim 1, wherein the lateral edge of the second electrode is laterally separated from the lateral edge of the first electrode by a distance less than 100 nm.

3. The image sensor defined in claim 1, wherein the insulator has a sloped lateral edge between the lateral edge of the second electrode and the lateral edge of the first electrode.

4. The image sensor defined in claim 3, wherein the second electrode has a smaller outline than the first electrode and wherein the sloped lateral edge of the insulator overlaps the first electrode.

5. The image sensor defined in claim 4, wherein the capacitor is formed on a substrate, wherein the second electrode is a top electrode, and wherein the first electrode is a bottom electrode between the top electrode and the substrate.

6. The image sensor defined in claim 1, wherein the given image sensor pixel comprises a photosensitive element, a floating diffusion region, and a transistor that couples the capacitor to the floating diffusion region.

7. The image sensor defined in claim 1, wherein the first electrode and the second electrode each comprise a refractory metal and wherein the insulator comprises a dielectric material having a dielectric constant that is greater than 5 and less than 50.

8. A method of forming a capacitor, the method comprising:
forming a first metal layer, an insulator layer, and a second metal layer on a substrate;
forming an etch masking layer on a portion of the second metal layer;
etching the second metal layer to form a top electrode for the capacitor while the etch masking layer is on the portion of the second metal layer;
etching the insulator layer to form an insulator for the capacitor while the etch masking layer is on the portion of the second metal layer; and
etching the first metal layer to form a bottom electrode for the capacitor while the etch masking layer is on the portion of the second metal layer, wherein the top electrode is formed with an edge and wherein the bottom electrode is formed with an edge that is laterally offset from the edge of the top electrode.

9. The method defined in claim 8, wherein etching the second metal layer comprises performing a reactive ion etch using first and second reactive gases and wherein etching the insulator layer comprises performing a reactive ion etch using the first reactive gas and a third reactive gas.

10. The method defined in claim 9, wherein the first reactive gas is boron trichloride, wherein the second reactive gas is sulfur hexafluoride, and wherein the third reactive gas is chlorine.

11. The method defined in claim 8, wherein etching the second metal layer comprises performing a reactive ion etch using a first total reactive gas flow rate and wherein etching the insulator layer comprises performing a reactive ion etch using a second total reactive gas flow rate greater than the first total reactive gas flow rate.

12. The method defined in claim 8, wherein etching the second metal layer comprises performing a reactive ion etch while providing a first gas pressure in a reactive ion etching chamber and wherein etching the insulator layer comprises performing a reactive ion etch while providing a second gas pressure, less than the first gas pressure, in the reactive ion etching chamber.

13. The method defined in claim 8, wherein etching the second metal layer comprises performing a reactive ion etch while providing a directional electric field having a first magnitude toward the substrate and wherein etching the insulator layer comprises performing a reactive ion etch while providing a directional electric field having a second magnitude, greater than the first magnitude.

14. The method defined in claim 8, wherein etching the insulator layer forms an insulator with a sloped edge that covers a portion of the first metal layer laterally beyond the edge of the top electrode and wherein the covered portion of the first metal layer at least partly defines the lateral offset between the edge of the top electrode and the edge of the bottom electrode.

15. The method defined in claim 8, wherein etching the first metal layer comprises performing a reactive ion etch after etching the insulator layer and wherein the reactive ion etch etches a portion of the top electrode to form the edge of the top electrode.

16. The method defined in claim 8, wherein the edge of the bottom electrode is laterally offset from the edge of the top electrode by a distance less than 50 nm.

17. The method defined in claim 8, wherein the first metal layer and the second metal layer each comprise a refractory metal and wherein the insulator layer comprises a dielectric material having a dielectric constant that is greater than 5 and less than 50.

18. A capacitor comprising:
a first electrode on a substrate;
an insulator on the first electrode; and
a second electrode on the insulator, wherein the first electrode has a peripheral edge and wherein the second electrode has a peripheral edge that is laterally offset from the peripheral edge of the first electrode by a separation less than 100 nm.

19. The capacitor defined in claim 18, wherein the insulator has a sloped peripheral edge between the peripheral edge of the first electrode and the peripheral edge of the second electrode.

20. The capacitor defined in claim 18, wherein the first electrode and the second electrode each comprise a refractory metal and wherein the insulator layer comprises a dielectric material having a dielectric constant that is greater than 5 and less than 50.
